(19) United States
(12) Patent Application Publication
(10) Pub. No.: US 2012/0170774 A1
(43) Pub. Date: Jul. 5, 2012

(54) AMPLIFIER CIRCUIT

(75) Inventors: TSUNG-JEN CHUANG, Tu-Cheng (TW); SHIH-FANG WONG, Tu-Cheng (TW); JIANG-FENG SHAN, Shenzhen City (CN); LIN-KUN DING, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/166,778

(22) Filed: Jun. 22, 2011

(30) Foreign Application Priority Data
Dec. 31, 2010 (CN) 201010619563.0

(51) Int. Cl. H03F 99/00

(52) U.S. Cl. 381/120

(57) ABSTRACT

An amplifier circuit for amplifying audio signal output by an audio source and outputting the amplified audio signal to a speaker is provided. The amplifier circuit includes a peripheral circuit and an amplifier chip including an amplifier, a first, a second, a third resistor, and a fourth resistor. The peripheral circuit includes a fifth and a sixth resistors. The first resistor is connected between a non-inverting input port and an output port of the amplifier, the second resistor is connected between an inverting input port and the output port of the amplifier, the third resistor is connected between the non-inverting input port and the fifth resistor, the fourth resistor is connected between the inverting port and the sixth resistor, the fifth and the sixth resistors are further respectively connected to an anode output port of the audio source and a cathode output port of the audio source.

### BACKGROUND

1. Technical Field

The present disclosure relates to amplifier circuits.

2. Description of Related Art

Amplifier circuits are a necessary part of audio equipment, such as, a tape recorder, a radio, or a media player. Usually, the amplifier circuit includes a special amplifier chip and corresponding peripheral circuits. As shown in FIG. 2, a prior amplifier circuit 1 connected between an audio source 2 and a speaker 3 is shown. The amplifier circuit 1 includes an amplifier chip 101 and a peripheral circuit 102. The amplifier chip 101 includes an amplifier A1 and resistors R1 and R2. The resistor R1 is connected between a non-inverting input port IN1 and an output port OUT of the amplifier A1, the resistor R2 is connected between an inverting input port IN2 and the output port OUT of the amplifier A1. Usually, the resistance value of the R1 is equal to the resistance value of R2. The peripheral circuit 102 includes resistors R3 and R4, and the resistor R3 is connected between an anode output port INP of the audio source 2 and the non-inverting input port IN1 of the amplifier A1, the resistor R4 is connected between a cathode output port INN of the audio source 2 and the inverting input port IN2 of the amplifier A1. In the prior amplifier circuit 1, the resistance value of the resistor R3 is also equal to the resistor R4 and much less than the ideal resistance value of the resistors R1 and R2. For example, the resistance value of the resistors R1 and R2 is 300 kilohm, and the resistance value of the resistors R3 and R4 is 20 kilohm.

Therefore, it is easy to know the amplification factor of the amplifier circuit 1 is equal to R1/R3=R2/R4=15. However, in general, the resistors R1 and R2 of the amplifier circuit 1 are Metal-Oxide-Semiconductor Field Effect Transistor (MOSFET) mode resistors, such as resistors between source and drain of the MOSFET, when the conduction degree of the MOSFET resistor is different, the resistance value of the MOSFET resistor is different. Therefore, the resistance values of the resistors R1 and R2 are difficult to control to a certain value. Usually, the actual resistance value of the resistors R1 and R2 have 20% bias compare to ideal resistance values of the resistors R1 and R2, and the resistors R3 and R4 are normal resistors, such as metal resistors and the resistance value of the R3 and R4 can maintain a certain value and equal to their ideal resistance values. Therefore, the actual amplification factor of the amplifier circuit 1 would be in the range from 300*(1−20%)/20=12 times to 300*(1+20%)/20=18.

However, if the amplification factor is not great, such as 12, the gain of audio signals output by the audio source is insufficient, if the amplification factor is too large, such as 18, the speaker has the risk of damage.

Therefore, it is desirable to provide an amplifier circuit to overcome the above-mentioned limitations.

### BRIEF DESCRIPTION OF THE DRAWINGS

Many aspects of the present disclosure should be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a circuit diagram of an amplifier circuit, in accordance with an exemplary embodiment.

FIG. 2 is a circuit diagram of an amplifier circuit in the related art.

### DETAILED DESCRIPTION

Embodiments of the present disclosure will now be described in detail below, with reference to the accompanying drawings.

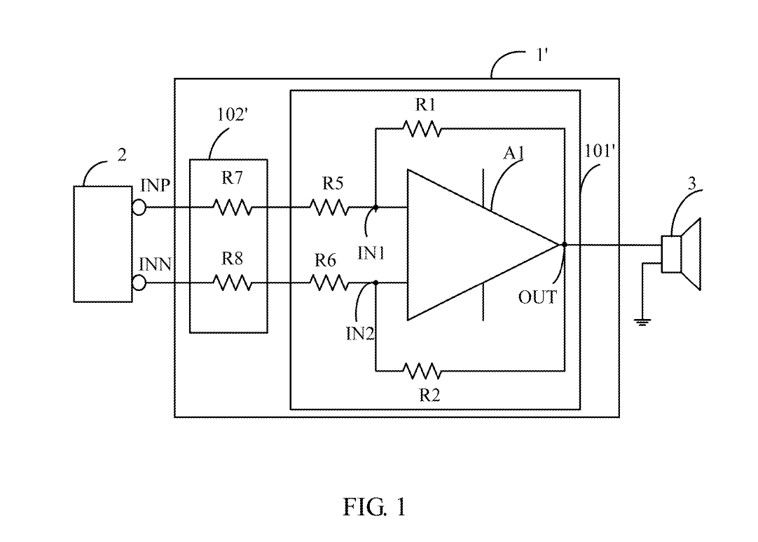

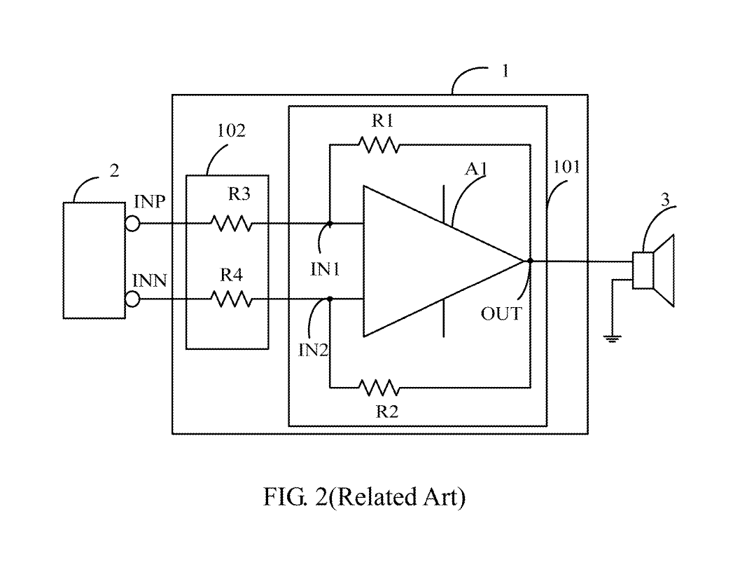

Referring to FIG. 1, comparing to the related art of FIG. 2, in the embodiment, an amplifier chip 101′ of an amplifier circuit 1′ further includes resistors R5 and R6, a peripheral circuit 102′ of the amplifier circuit 1′ includes resistors R7 and R8. As shown in FIG. 1, the resistor R1 of the amplifier circuit 1′ is connected between the non-inverting input port IN1 of the amplifier A1 and the output port OUT of the amplifier A1, the resistor R2 is connected between the inverting input port IN2 of the amplifier A1 and the output port OUT of the amplifier A1, the resistor R5 is connected between the non-inverting input port IN1 and the resistor R7, the resistor R6 is connected between the inverting port IN2 and the resistor R8, the resistors R7 and R8 are respectively connected to the anode output port INP and the cathode output port INN of the audio source 2 also.

In the embodiment, the resistors R5 and R6 are MOSFET mode resistors, the resistors R7 and R8 are normal resistors. The sum of the ideal resistance values of the resistors R5 and R7 is equal to the resistance value of the resistor R3 of FIG. 2, and the sum of the ideal resistance values of the resistors R6 and R8 is equal to the resistance value of the resistor R4 of FIG. 2. In the embodiment, the ideal resistance values of the all of resistors R5, R6, R7, and R8 are 10 kilohm. In the embodiment, the actual resistance value of the resistors R5, R6 are changed following the resistors R1, R2, namely, if the resistance value of the resistors R1, R2 are biased 10%, the resistance value of the resistors R5, R6 are also biased 10%.

The amplification factor of the amplifier circuit 1′ is R1/(R5+R7)=R2/(R6+R8), if the resistance values of the resistors R1, R2, R5, R6 have no bias, namely equal to the ideal resistance value, the actual resistance values of the resistors R1, R2, R5, R6 are equal to the ideal resistance values of the resistors R1, R2, R5, R6, then the amplification factor of the amplifier circuit 1′ is 300/(10+10)=15. As described in background, the resistance values of the resistors R1, R2 have bias less than 20%, namely the actual resistance values of the resistors R1, R2 are located in the range from 300*(1−20%) to 300*(1+20%). Because the resistance values of the resistors R5, R6 have the same bias as the resistor R1, R2, then the actual resistance values of the resistors R5, R6 are located in the range from 10*(1−20%) to 10*(1+20%). Therefore, the actual amplification factor of the amplifier circuit 1′ is located in the range from 300*0.8/(10*0.8+10)=13.3 to 300*1.2/(10*1.2+10)=16.36. Compare to the range of the actual amplification factor of the amplifier circuit 1 of FIG. 2, the bias of the actual amplification factor of the amplifier circuit 1′ in the embodiment is decreased.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being exemplary embodiments of the present disclosure.

What is claimed is:

1. An amplifier circuit for amplifying audio signal output by an audio source and outputting the amplified audio signal to a speaker, comprising:
an amplifier chip comprising a first resistor, a second resistor, a third resistor, a fourth resistor, and an amplifier comprising an inverting input port, a non-inverting input port, and an output port, and
a peripheral circuit comprising a fifth resistor and a sixth resistor;
wherein, the first resistor is connected between the non-inverting input port of the amplifier and the output port of the amplifier, the second resistor is connected between the inverting input port of the amplifier and the output port of the amplifier, the third resistor is connected between the non-inverting input port and the fifth resistor, the fourth resistor is connected between the inverting port and the sixth resistor, the fifth resistor and the sixth resistor are respectively connected to an anode output port of the audio source and a cathode output port of the audio source.

2. The amplifier circuit according to claim 1, wherein the first resistor, the second resistor, the third resistor, and the fourth resistor are MOSFET mode resistors, the fifth resistor and the six resistor are metal resistors.

3. The amplifier circuit according to claim 2, wherein the resistance value of the third resistor and the fourth resistor have the same bias as that of the first resistor and the second resistor.

4. The amplifier circuit according to claim 1, wherein the resistance values of the third resistor and the fourth resistor are respectively the same as those of the fifth resistor and the six resistor.
